(19) United States
(12) Patent Application Publication
(10) Pub. No.: US 2025/0305816 A1
(43) Pub. Date: Oct. 2, 2025

(54) DETECTION METHOD AND PROCESSING APPARATUS

(71) Applicant: DISCO CORORATION, Tokyo (JP)

(72) Inventor: Kazuma SEKIYA, Tokyo (JP)

(21) Appl. No.: 19/081,218

(22) Filed: Mar. 17, 2025

(30) Foreign Application Priority Data
Mar. 29, 2024 (JP) 2024-055613

(51) Int. Cl. G01B 11/27; H01L 21/68

(52) U.S. Cl. CPC G01B 11/272; H01L 21/681

(57) ABSTRACT

There is provided a detection method for detecting a mark that is formed at an outer peripheral edge of a semiconductor wafer. The detection method includes rotating the semiconductor wafer relative to measurement light in one direction, receiving the measurement light transmitted or reflected by the mark, and detecting that received light intensity of the measurement light has started decreasing after reaching a maximum value, then rotating the semiconductor wafer relative to the measurement light in an opposite direction and receiving the measurement light transmitted or reflected by the mark, determining an area where the received light intensity of the measurement light takes the maximum value as a center of the mark, and, after the rotating the semiconductor wafer relative to the measurement light in the opposite direction and receiving the measurement light transmitted or reflected by the mark, stopping the rotation at the center of the mark.

### BACKGROUND OF THE INVENTION

### Field of the Invention

The present invention relates to a detection method for detecting a mark that is formed at an outer peripheral edge of a semiconductor wafer and is indicative of crystal orientation, and a processing apparatus therefor.

### Description of the Related Art

A wafer made of a semiconductor material such as silicon is formed with a cutout, such as a notch or an orientation flat, at an outer periphery of the wafer as a mark indicative of crystal orientation, and devices are formed thereon according to the crystal orientation.

Further, there is also devised a technique for forming a flat part in a chamfered portion of the outer periphery of the wafer as a mark indicative of crystal orientation in order to increase the number of devices allowed to be formed on a front surface of the wafer compared to the case of forming a notch or an orientation flat (see Japanese Patent Laid-open No. 2007-189093).

Such marks indicative of crystal orientation as described above are used in alignment at the time of processing wafers in a manufacturing process of semiconductor devices. A photoelectric sensor, for example, is used in this alignment, and, in a common method, the crystal orientation is detected at the time when the amount of received light that has been transmitted or reflected exceeds a threshold.

### SUMMARY OF THE INVENTION

However, since a mark indicative of crystal orientation has a predetermined width, there arises a problem that, in the case of using a notch or an orientation flat as described above, the amount of received light exceeds the threshold short of a center of the flat part, resulting in only rough alignment.

In order to solve this problem, there has been devised another method for minimizing errors by bringing the threshold closer to a peak value of received light intensity, but this method is apt to suffer erroneous detections caused by temporal changes of the photoelectric sensor or the like.

Accordingly, it is an object of the present invention to provide a method for precisely detecting a center of a mark that is formed in a wafer and is indicative of crystal orientation, and a processing apparatus therefor.

In accordance with an aspect of the present invention, there is provided a detection method for detecting a mark that is formed at an outer peripheral edge of a semiconductor wafer and is indicative of crystal orientation, the detection method including irradiating the outer peripheral edge of the semiconductor wafer with measurement light while rotating the semiconductor wafer relative to the measurement light in one direction about a rotation axis passing through a center of the semiconductor wafer, receiving the measurement light transmitted or reflected by the mark, and detecting that received light intensity of the measurement light has started decreasing after reaching a maximum value, then rotating the semiconductor wafer relative to the measurement light in a direction opposite to the one direction and receiving the measurement light transmitted or reflected by the mark, in the rotating the semiconductor wafer relative to the measurement light in the one direction and detecting that the received light intensity of the measurement light has started decreasing after reaching the maximum value or in the rotating the semiconductor wafer relative to the measurement light in the opposite direction and receiving the measurement light transmitted or reflected by the mark, determining an area where the received light intensity of the measurement light takes the maximum value as a center of the mark, and, after the rotating the semiconductor wafer relative to the measurement light in the opposite direction and receiving the measurement light transmitted or reflected by the mark, stopping the rotation of the semiconductor wafer relative to the measurement light at the center of the mark.

With this configuration, after it is detected that the received light intensity of the measurement light transmitted or reflected by the mark indicative of the crystal orientation has started decreasing after reaching the maximum value, the semiconductor wafer is rotated relative to the measurement light in the opposite direction, and then the rotation of the semiconductor wafer is stopped in a state in which the center of the mark coincides with the measurement light. Consequently, an error between the measurement light and the center of the mark at the stopped position can be minimized. Thus, positioning accuracy can be enhanced as compared to the related-art case in which the relative rotation is stopped at the time when the amount of received light exceeds a threshold.

Further, in the case of setting a threshold as in the related art, it is important to set a threshold in order to minimize an error between the measurement light and the center of the mark at the stopped position. With the configuration described above, in contrast, it is not necessary to set a threshold, and the positioning accuracy can be enhanced.

Preferably, in the rotating the semiconductor wafer relative to the measurement light in the opposite direction and receiving the measurement light transmitted or reflected by the mark, an area where the received light intensity of the measurement light takes the maximum value is determined as the center of the mark, and the rotation of the semiconductor wafer relative to the measurement light is continued until determination of the center of the mark.

With this configuration, in the rotating the semiconductor wafer relative to the measurement light in the one direction and detecting that the received light intensity of the measurement light has started decreasing after reaching the maximum value, the position at which to invert the rotation direction is detected, and, in the rotating the semiconductor wafer relative to the measurement light in the opposite direction and receiving the measurement light transmitted or reflected by the mark, an area where the received light intensity of the measurement light takes the maximum value is determined as the center of the mark, and the rotation is stopped at the center of the mark. Consequently, the positioning accuracy can be enhanced.

Preferably, a rotation speed in the rotating the semiconductor wafer relative to the measurement light in the opposite direction and receiving the measurement light transmitted or reflected by the mark is set lower than a rotation speed in the rotating the semiconductor wafer relative to the measurement light in the one direction and detecting that the received light intensity of the measurement light has started decreasing after reaching the maximum value. With this configuration, the rotation speed is lowered in determining the center of the mark, and hence, the accuracy of detecting the center of the mark is enhanced, resulting in enhancement of the accuracy of positioning the wafer. Further, in the rotating the semiconductor wafer relative to the measurement light in the one direction and detecting that the received light intensity of the measurement light has started decreasing after reaching the maximum value, the relative rotation is performed at a relatively high speed, so that the time taken for the detection processing can be shortened.

Preferably, in the rotating the semiconductor wafer relative to the measurement light in the one direction and detecting that the received light intensity of the measurement light has started decreasing after reaching the maximum value, an area where the received light intensity of the measurement light takes the maximum value is determined as the center of the mark, and, in the rotating the semiconductor wafer relative to the measurement light in the opposite direction and receiving the measurement light transmitted or reflected by the mark, the rotation of the semiconductor wafer relative to the measurement light is continued until the measurement light is located at the center of the mark.

With this configuration, in the rotating the semiconductor wafer relative to the measurement light in the one direction and detecting that the received light intensity of the measurement light has started decreasing after reaching the maximum value, an area where the received light intensity of the measurement light takes the maximum value is determined as the center of the mark, and, in the rotating the semiconductor wafer relative to the measurement light in the opposite direction and receiving the measurement light transmitted or reflected by the mark, the semiconductor wafer is returned to the area where the received light intensity of the measurement light takes the maximum value before the rotation is stopped. Consequently, the center of the mark can further precisely be detected.

Preferably, the detection method further includes setting a threshold to the received light intensity of the measurement light, and detecting the received light intensity of the measurement light exceeding the threshold. In the rotating the semiconductor wafer relative to the measurement light in the one direction and detecting that the received light intensity of the measurement light has started decreasing after reaching the maximum value, when the received light intensity of the measurement light exceeds the threshold, a rotation speed is made lower than a rotation speed adopted before the threshold is exceeded.

With this configuration, in the rotating the semiconductor wafer relative to the measurement light in the one direction and detecting that the received light intensity of the measurement light has started decreasing after reaching the maximum value, the relative rotation is performed at a relatively high speed until the threshold is exceeded, so that the time taken for the detection processing can be shortened. Further, the rotation speed is lowered after the threshold is exceeded, and hence, the detection accuracy can be enhanced.

Preferably, the mark is a flat mirror surface part formed at a position overlapping a chamfered portion at an outer periphery of the semiconductor wafer as viewed in a direction of the rotation axis, and, in the rotating the semiconductor wafer relative to the measurement light in the one direction and detecting that the received light intensity of the measurement light has started decreasing after reaching the maximum value, and in the rotating the semiconductor wafer relative to the measurement light in the opposite direction and receiving the measurement light transmitted or reflected by the mark, the semiconductor wafer is irradiated with the measurement light from a side, and measurement light reflected by the flat mirror surface part is received.

With this configuration, since the mark indicative of the crystal orientation is constituted by the flat mirror surface part formed at the position overlapping the chamfered portion at the outer periphery of the semiconductor wafer, that area on the semiconductor wafer in which devices are to be formed can be secured as large as possible, and hence, the number of device chips manufactured from one wafer can be increased. In addition, since the mark is a flat mirror surface part lying in perpendicular to a planar direction of the semiconductor wafer and accurately reflects light incident from a side, a noncontact light reflection method having no possibility of damaging the semiconductor wafer can suitably be adopted as the mark detection method.

In accordance with another aspect of the present invention, there is provided a processing apparatus for detecting a mark that is formed at an outer peripheral edge of a semiconductor wafer and is indicative of crystal orientation, the processing apparatus including a holding table for holding the semiconductor wafer thereon, a crystal orientation detection sensor having a light projector that irradiates the mark in the semiconductor wafer with measurement light and a light receiver that receives measurement light transmitted or reflected by the mark, a rotation driving unit that rotates the holding table relative to the crystal orientation detection sensor about a rotation axis passing through a center of the holding table, and a controller. The controller includes a rotation direction control section that controls a rotation direction of the relative rotation, a rotation stop control section that stops the relative rotation, and a mark center detection section that determines an area where received light intensity of the measurement light takes a maximum value as a center of the mark. The rotation direction control section changes the rotation direction of the relative rotation after, while the holding table is being rotated relative to the crystal orientation detection sensor in a predetermined direction, it is detected that the received light intensity of the measurement light has started decreasing after reaching the maximum value, and the rotation stop control section stops the relative rotation at the center of the mark after the rotation direction of the relative rotation is changed.

With this configuration, the rotation of the semiconductor wafer is stopped in a state in which the center of the mark that is formed in the semiconductor wafer and is indicative of crystal orientation coincides with the measurement light, so that the positioning accuracy can be enhanced. As a result, alignment processing for positioning at a subsequent stage can be simplified or omitted.

Preferably, the controller further includes a rotation speed control section that controls a rotation speed of the relative rotation. With this configuration, the rotation speed of the relative rotation is variable, and hence, the detection accuracy can be enhanced while the time taken for the detection processing is shortened.

Preferably, the mark center detection section detects the center of the mark while the holding table is being rotated relative to the crystal orientation detection sensor in a direction opposite to the predetermined direction, and the rotation speed control section makes a rotation speed of the relative rotation in the opposite direction lower than a rotation speed of the relative rotation in the predetermined direction.

With this configuration, the rotation speed is lowered in the rotation in the opposite direction for determining the center of the mark, and hence, the accuracy of detecting the center of the mark is enhanced, resulting in enhancement of the accuracy of positioning the wafer. Further, before that, in the rotation in the predetermined direction, the relative rotation is performed at a relatively high speed, and hence, the time taken for the detection processing can be shortened.

Preferably, the controller further includes a threshold setting section that sets a threshold to the received light intensity of the measurement light, and a threshold detection section that detects the received light intensity of the measurement light exceeding the threshold. The mark center detection section detects the center of the mark while the holding table is being rotated relative to the crystal orientation detection sensor in the predetermined direction, and, when the threshold detection section detects the received light intensity of the measurement light exceeding the threshold, the rotation speed control section makes the rotation speed lower than the rotation speed adopted before the threshold is exceeded.

With this configuration, the area where the received light intensity of the measurement light takes the maximum value is determined as the center of the mark in the rotation in the predetermined direction, and the semiconductor wafer is returned to the area where the received light intensity of the measurement light takes the maximum value in the rotation in the opposite direction, before the rotation is stopped. Consequently, the center of the mark can further precisely be detected.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a semiconductor wafer according to one embodiment of the present invention;

FIG. 2 is a plan view of the semiconductor wafer illustrated in FIG. 1, the semiconductor wafer being formed thereon with a plurality of devices in a partitioned manner;

FIG. 3 is a cross-sectional view taken along line A-A indicated in FIG. 2;

FIG. 4 is a cross-sectional view taken along line B-B indicated in FIG. 2;

FIG. 5 is a conceptual diagram of a processing apparatus that detects a mark indicative of crystal orientation of the semiconductor wafer according to one embodiment of the present invention;

FIG. 6 is a flowchart of a detection method according to a first embodiment of the present invention;

FIGS. 7A to 7F are views illustrating positions of measurement light and the mark in detecting steps in the first embodiment;

FIG. 8 is a graph indicating received light intensity of reflected light in detecting steps (A) to (F) in the first embodiment;

FIG. 9 is a flowchart of a detection method according to a second embodiment of the present invention;

FIGS. 10A to 10F are views illustrating positions of the measurement light and the mark in detecting steps in the second embodiment;

FIG. 11 is a graph indicating received light intensity of reflected light in detecting steps (A) to (F) in the second embodiment;

FIG. 12 is a perspective view of a semiconductor wafer according to a first modification example;

FIG. 13 is a perspective view of a semiconductor wafer according to a second modification example; and

FIG. 14 is a conceptual diagram of a processing apparatus according to a modification example.

### DETAILED DESCRIPTION OF THE PREFERRED EMBODIMENTS

A detection method and a processing apparatus according to embodiments of the present invention will be described below with reference to the drawings.

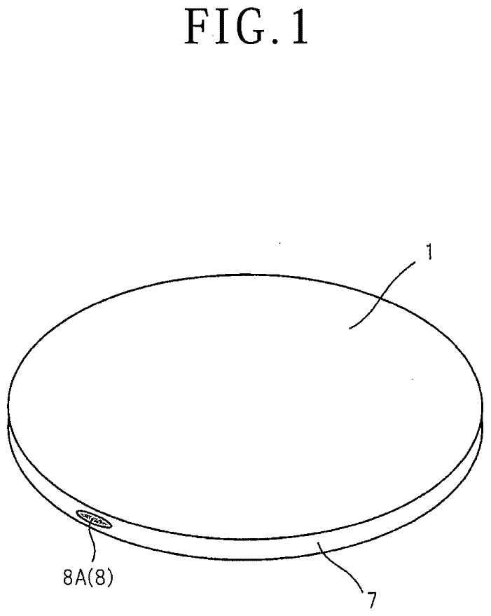

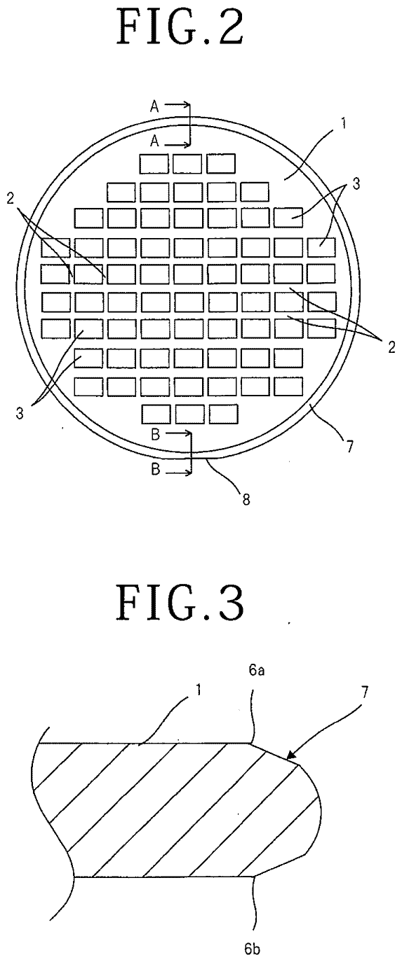

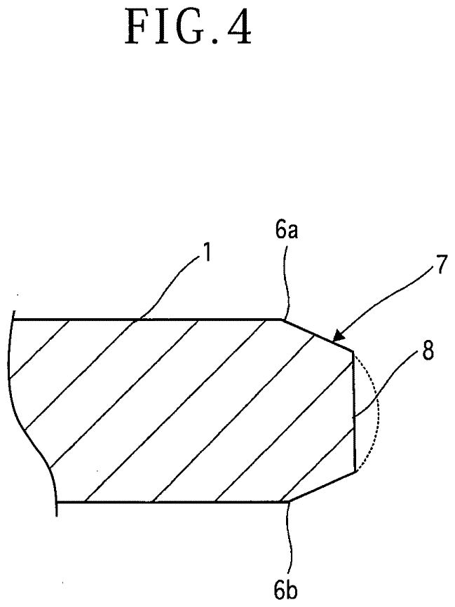

Description is first made of a semiconductor wafer 1 which is a processing target of the detection method and the processing apparatus of the present invention, with reference to FIG. 1 to FIG. 4. FIG. 1 is a perspective view of a semiconductor wafer according to one embodiment, FIG. 2 is a plan view of the semiconductor wafer illustrated in FIG. 1, the semiconductor wafer being formed thereon with a plurality of devices 3 in a partitioned manner, FIG. 3 is a cross-sectional view taken along line A-A indicated in FIG. 2, and FIG. 4 is a cross-sectional view taken along line B-B indicated in FIG. 2.

The semiconductor wafer (hereinafter referred to as a wafer) 1, for example, is made of single crystal silicon having crystal orientation properties and is in a disk shape. A thickness of the wafer 1 is approximately 600 um, for example. The wafer 1 has a front surface partitioned into a plurality of regions by a plurality of planned division lines 2 formed in a lattice pattern, and rectangular devices 3 are formed in the respective regions as illustrated in FIG. 2. An electronic circuit is formed on a front surface of each of the devices 3.

The wafer 1 has an outer peripheral end chamfered from a front surface side to a back surface side, so that a chamfered portion 7 having an arc-shaped or tapered cross section is formed between a front surface edge 6a and a back surface edge 6b, which are each in a perfect circle shape. Formation of the chamfered portion 7 prevents a crack, chipping, or dust generation from occurring in the wafer 1 due to an inadvertent impact. It is to be noted that the chamfered portion 7 need not necessarily be formed over an entire area ranging from the front surface edge 6a to the back surface edge 6b and may partially include an unchamfered area, for example, in an intermediate portion between the front surface edge 6a and the back surface edge 6b. The chamfered portion 7 can thus be regarded as an area overlapping a chamfered area as viewed in a direction perpendicular to a planar direction (the front surface and the back surface lying parallel with each other) of the wafer 1.

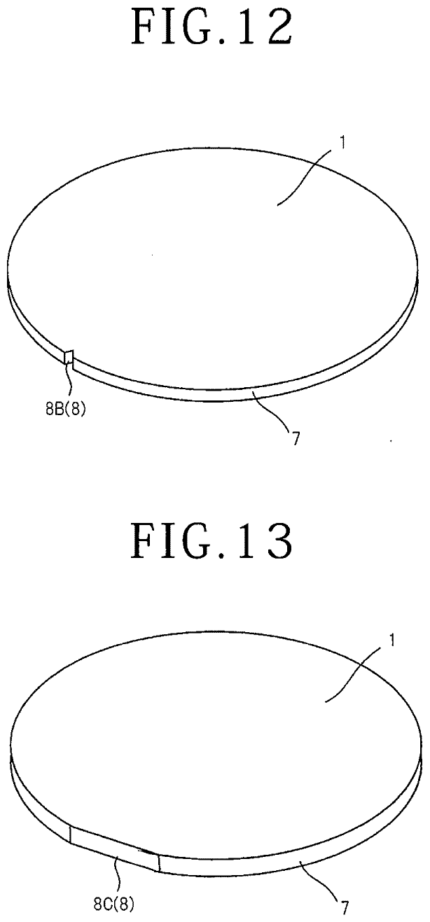

At a predetermined location in the chamfered portion 7, a mark 8 indicative of crystal orientation is formed as illustrated in FIG. 1 and FIG. 2. The mark 8 is a minute flat mirror surface part 8A formed by cutting out a part of an outermost peripheral edge of the chamfered portion 7 in such a manner as to form a flat surface. The minute flat mirror surface part 8A is formed as a mark indicative of crystal orientation at such a position that a straight line connecting a center of the wafer 1 and the mark 8 extends in parallel to or perpendicularly to the planned division lines 2 formed in the lattice pattern. Alternatively, the mark 8 may be a notch 8B illustrated in FIG. 12 or may be an orientation flat 8C illustrated in FIG. 13. The minute flat mirror surface part 8A is more advantageous than such marks as the notch 8B and the orientation flat 8C in that the number of device chips manufactured from one wafer 1 can be increased.

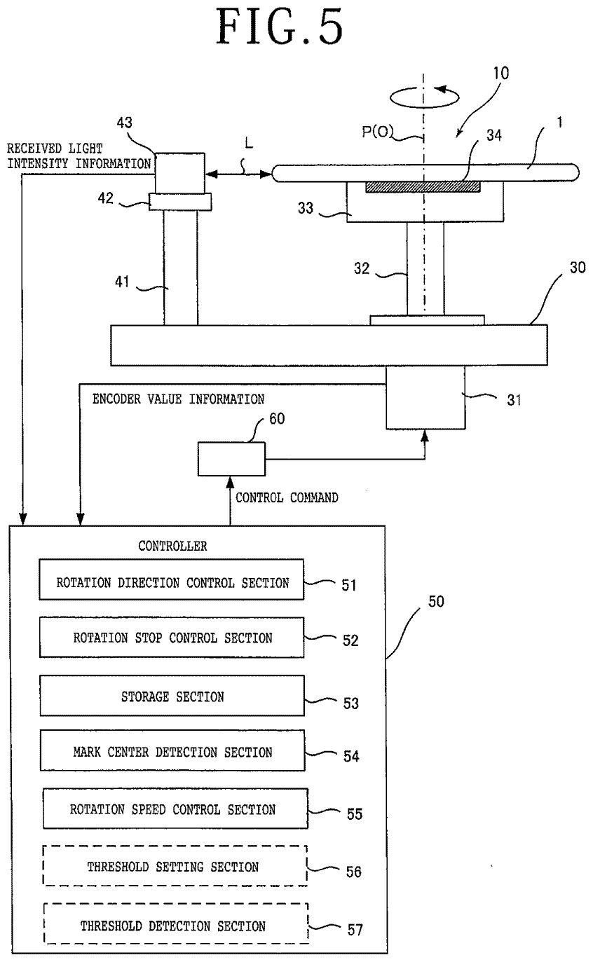

Description is next made of a processing apparatus 10 according to one embodiment of the present invention with reference to FIG. 5. In FIG. 5, reference symbol 30 denotes a base frame of a mark detection mechanism. As the base frame 30, for example, a frame of a device formation apparatus or the like is used. An alternating-current (AC) servo motor 31 incorporating an encoder is attached to the base frame 30, and a rotary table 33 is attached to an output shaft of the AC servo motor 31 through a table post 32. The rotary table 33 has an upper surface in which a porous portion 34 is disposed. Meanwhile, a hole communicating with the porous portion 34 is defined inside each of the table post 32 and the rotary table 33, and the wafer 1 is held under suction on the porous portion 34 when an unillustrated vacuum suction device connected to the hole is actuated.

A bracket 42 is attached to the base frame 30 through a sensor post 41, and an optical sensor 43 is attached to the bracket 42. The optical sensor 43 has a light projector and a light receiver, an optical axis L of them is oriented to a side surface of the wafer 1, and the optical axis L has its height set coinciding with the height of a center of the wafer 1 in a thickness direction. It is to be noted that the height of the optical axis L and the angle of the optical sensor 43 can be freely set as long as the optical sensor 43 can receive reflected light.

The processing apparatus 10 further includes a controller 50 and a motor driver 60. Light projected from the light projector of the optical sensor 43 is reflected by the side surface of the wafer 1. When the mark 8 has come to a position right in front of the optical sensor 43 as a result of rotation of the wafer 1, received light intensity of the reflected light received by the light receiver becomes the maximum. The controller 50 is constituted by a computer including an arithmetic processing device having a microprocessor such as a central processing unit (CPU), a storage device having a memory such as a read only memory (ROM) or a random access memory (RAM), and an input/output interface device.

The controller 50 receives an input of received light intensity information corresponding to the received light intensity from the optical sensor 43 and an input of encoder value information from the encoder of the AC servo motor 31. The controller 50 includes a rotation direction control section 51 that controls a rotation direction of the AC servo motor 31, a rotation stop control section 52 that stops the rotation of the AC servo motor 31, a storage section 53 that stores the received light intensity information and encoder values in association with each other, a mark center detection section 54 that determines an area in which the received light intensity of the reflected light takes the maximum value, as the center of the mark 8, and a rotation speed control section 55 that controls a rotation speed of the AC servo motor 31. It is to be noted that the controller 50 is not limited to the configuration described above, and that the controller 50 may not include some of the functional sections or may include other functional sections. For example, although not required in a detection method according to a first embodiment described later, a threshold setting section 56 and a threshold detection section 57 are preferably further provided in a detection method according to a second embodiment described later.

The rotation direction control section 51 controls a rotation direction of the wafer 1 held on the rotary table 33, by controlling the rotation direction of the AC servo motor 31. In the detection method for detecting the mark 8 described later, the rotation direction control section 51 inverts the rotation direction of the wafer 1 at least once.

The rotation stop control section 52 stops the rotation of the wafer 1 held on the rotary table 33, by stopping the rotation of the AC servo motor 31. In the detection method for detecting the mark 8 described later, the rotation stop control section 52 stops the rotation of the wafer 1 at least twice. The first stop is made when the rotation direction control section 51 inverts the rotation direction, and the second stop is made to position the wafer 1. The orientation of the positioned wafer 1 remains constant, and the wafer 1 is delivered to a subsequent step with the orientation kept unchanged. The storage section 53 stores the received light intensity information and encoder values obtained at the time of rotation of the wafer 1 in association with each other.

The mark center detection section 54 determines, as the center of the mark 8, a position where the received light intensity takes the maximum value, in reference to the received light intensity information obtained at the time of rotation of the wafer 1. In a case where there is only one position where the received light intensity takes the maximum value, the mark center detection section 54 can determine that position as the center of the mark 8. Meanwhile, in a case where there are a plurality of positions where the received light intensity takes the maximum value, the mark center detection section 54 can determine, for example, any one of a first position, an intermediate position, and a last position as the center of the mark 8. It is to be noted that, in an actual case where the detection is carried out concurrently with the measurement of the received light intensity, the position where the received light intensity takes the maximum value can include both the position where the received light intensity takes the maximum value and a position where the received light intensity has just started decreasing from the maximum value. Thus, when these positions are referred to as the area where the received light intensity takes the maximum value, the mark center detection section 54 determines the area where the received light intensity takes the maximum value as the center of the mark 8.

The rotation speed control section 55 controls a rotation speed of the wafer 1 held on the rotary table 33, by controlling the rotation speed of the AC servo motor 31. The threshold setting section 56 sets a threshold to the received light intensity of measurement light in advance. This threshold is a threshold for use in changing the rotation speed. The setting of the threshold (threshold setting step) is carried out before the detection processing is started. The threshold detection section 57 detects the received light intensity of the measurement light exceeding the threshold set by the threshold setting section 56.

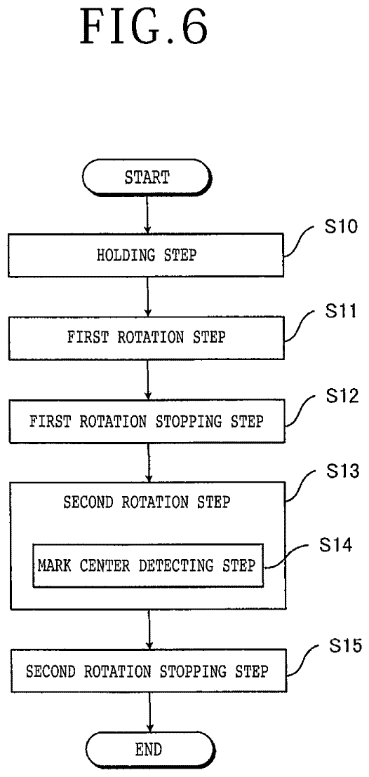

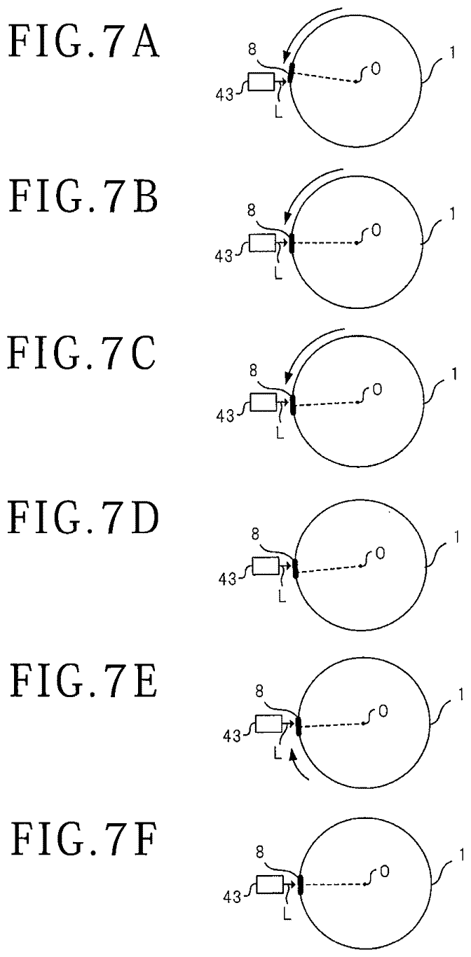

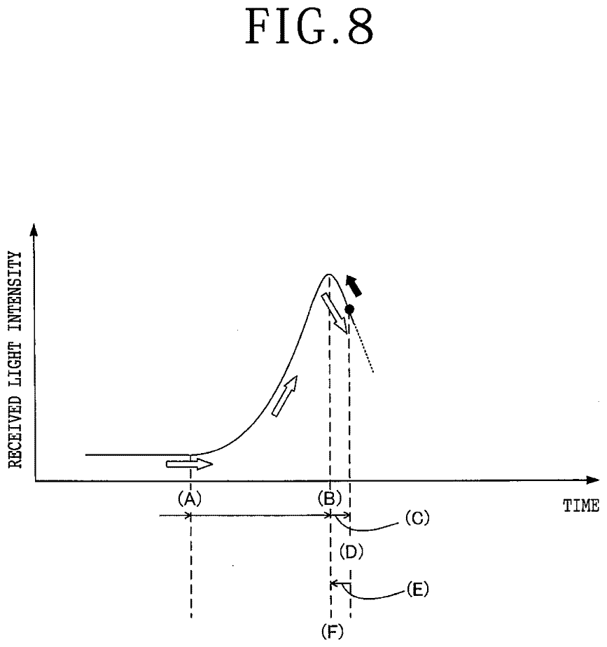

Now, the detection method for detecting the mark 8 according to the first embodiment is described with reference to FIG. 6 to FIG. 8. FIG. 6 is a flowchart of the detection method according to the first embodiment of the present invention, FIGS. 7A to 7F are views illustrating positions of the measurement light and the mark 8 in detecting steps, and FIG. 8 is a graph indicating the received light intensity of the reflected light in the detecting steps. Each broken line in FIGS. 7A to 7F indicates a line connecting a center O of the wafer 1 and a center of the mark 8 in a circumferential direction. In FIGS. 7A to 7F and FIG. 8, arrows indicate the rotation direction and the rotation speed. More specifically, in FIGS. 7A to 7F, the direction of each arrow represents the rotation direction, and the length of each arrow represents the rotation speed. In FIG. 8, white arrows represent a rotation direction different from that represented by a black arrow, and the length of each of the white arrows and the black arrow represents the rotation speed. A longer arrow means a higher rotation speed.

The detection method of the first embodiment includes a holding step S10, a first rotation step S11, a first rotation stopping step S12, a second rotation step S13, a mark center detecting step S14, and a second rotation stopping step S15 as illustrated in FIG. 6. In the detection method of the present embodiment, the mark center detecting step S14 is carried out in the second rotation step S13.

The holding step S10 is a step of holding the wafer 1 on the rotary table 33. In the holding step S10, the wafer 1 is placed on the rotary table 33 in such a manner that the center o thereof coincides with a rotation axis P of the rotary table 33, and then is held under suction on the rotary table 33.

In the first rotation step S11, the rotary table 33 holding the wafer 1 thereon is rotated in one direction (hereinafter referred to as a normal rotation direction). At this time, the AC servo motor 31 rotates, and orientation of the rotary table 33 is input as an encoder value to the controller 50. Meanwhile, the optical sensor 43 projects light from the light projector to the side surface of the wafer 1, and the received light intensity of reflected light received by the light receiver is input as received light intensity information to the controller 50.

At the position of FIG. 7A, the mark 8 deviates from the optical axis L of the optical sensor 43, and hence, the received light intensity of the reflected light is extremely low as indicated by (A) in FIG. 8. When the wafer 1 is further rotated in the normal rotation direction from the position of FIG. 7A, the mark 8 overlaps the optical axis L of the optical sensor 43, and hence, the received light intensity gradually increases as indicated in FIG. 8. It is to be noted that rotation in the normal rotation direction is indicated by a counterclockwise arrow in FIGS. 7A to 7F and is indicated by a white arrow in FIG. 8.

At the position of FIG. 7B, the center of the mark 8 coincides with the optical axis L of the optical sensor 43, and hence, the received light intensity of the reflected light takes the maximum value as indicated by (B) in FIG. 8.

When the wafer 1 is further rotated in the normal rotation direction from the position of FIG. 7B, the center of the mark 8 deviates from the optical axis L of the optical sensor 43, and hence, the received light intensity gradually decreases as indicated in FIG. 8. More specifically, at the position of FIG. 7C, although the mark 8 overlaps the optical axis L of the optical sensor 43, the center of the mark 8 has deviated from the optical axis L of the optical sensor 43, and hence, the received light intensity of the reflected light decreases from the maximum value as indicated by (C) in FIG. 8.

In the first rotation stopping step S12, it is detected that the received light intensity of the reflected light has started decreasing after reaching the maximum value, and the rotation of the wafer 1 in the normal rotation direction is then stopped. FIG. 7D indicates a state in which the rotation of the wafer 1 has been stopped in the first rotation stopping step S12. At the position of FIG. 7D, the center of the mark 8 deviates from the optical axis L of the optical sensor 43, and hence, the received light intensity of the reflected light is lower than the maximum value as indicated by (D) in FIG. 8.

In the second rotation step S13, the rotary table 33 holding the wafer 1 thereon is rotated in a direction (hereinafter referred to as a reverse rotation direction) opposite to the normal rotation direction in which the rotary table 33 has been rotated in the first rotation step S11. At this time as well, the AC servo motor 31 rotates, and the orientation of the rotary table 33 is input as an encoder value to the controller 50.

Meanwhile, the optical sensor 43 projects light from the light projector to the side surface of the wafer 1, and the received light intensity of reflected light received by the light receiver is input as received light intensity information to the controller 50. It is to be noted that rotation in the reverse rotation direction is indicated by a clockwise arrow in FIGS. 7A to 7F and is indicated by a black arrow in FIG. 8.

At the position of FIG. 7E, although the mark 8 overlaps the optical axis L of the optical sensor 43, the center of the mark 8 deviates from the optical axis L of the optical sensor 43. Hence, the received light intensity of the reflected light is lower than the maximum value as indicated by (E) in FIG. 8, but the received light intensity increases as the wafer 1 is further rotated in the opposite direction.

In the mark center detecting step S14, the area where the received light intensity of the reflected light takes the maximum value is determined as the center of the mark 8. Since, in the second rotation step S13, the received light intensity increases as the wafer 1 is rotated in the reverse rotation direction, the mark center detection section 54 determines the area where the received light intensity takes the maximum value as the center of the mark 8.

In the second rotation stopping step S15, the rotation of the wafer 1 is stopped immediately after the detection of the center of the mark 8 in the mark center detecting step S14. FIG. 7F indicates a state in which the rotation of the wafer 1 has been stopped in the second rotation stopping step S15. At the position of FIG. 7F, the center of the mark 8 coincides with the optical axis L of the optical sensor 43, and hence, the received light intensity of the reflected light takes the maximum value as indicated by (F) in FIG. 8.

As described above, after it is detected that the received light intensity of the light reflected by the mark 8 indicative of the crystal orientation has started decreasing after reaching the maximum value, the wafer 1 is rotated in the opposite direction, and then the rotation of the wafer 1 is stopped when the center of the mark 8 coincides with the measurement light. Consequently, an error between the measurement light and the center of the mark 8 at the stopped position can be minimized. Thus, positioning accuracy can be enhanced as compared to the related-art case in which the rotation is stopped at the time when the amount of received light exceeds a threshold.

Moreover, in the present embodiment, the position at which to invert the rotation direction is detected in the first rotation step S11, and the area where the received light intensity of the reflected light takes the maximum value is determined as the center of the mark 8 in the second rotation step S13, as described above.

Here, for the purpose of enhancing the accuracy of detection of the mark 8, it is preferable that the rotation speed of the wafer 1 in the second rotation step S13 be set lower than the rotation speed of the wafer 1 in the first rotation step S11. That is, at the time of rotation of the wafer 1 in the second rotation step S13, the rotation speed control section 55 makes the rotation of the wafer 1 slower than that in the first rotation step S11. This enhances the detection accuracy in the mark center detecting step S14 in the second rotation step S13, and thus enhances the accuracy of positioning the wafer 1. In addition, the wafer 1 can be rotated at a high speed in the first rotation step S11, so that the time taken until the end of the detection processing can be shortened.

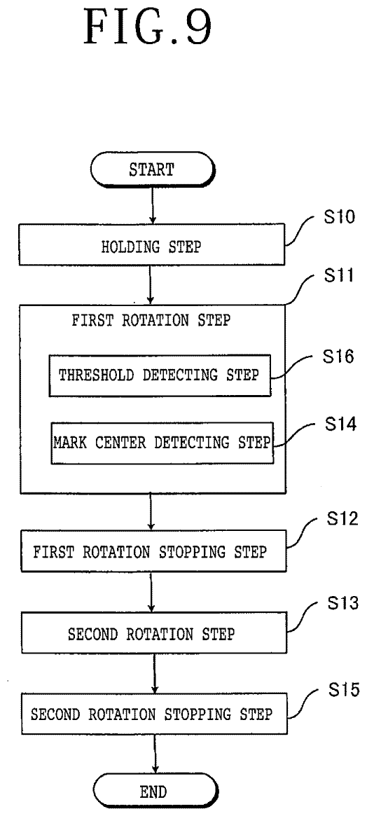

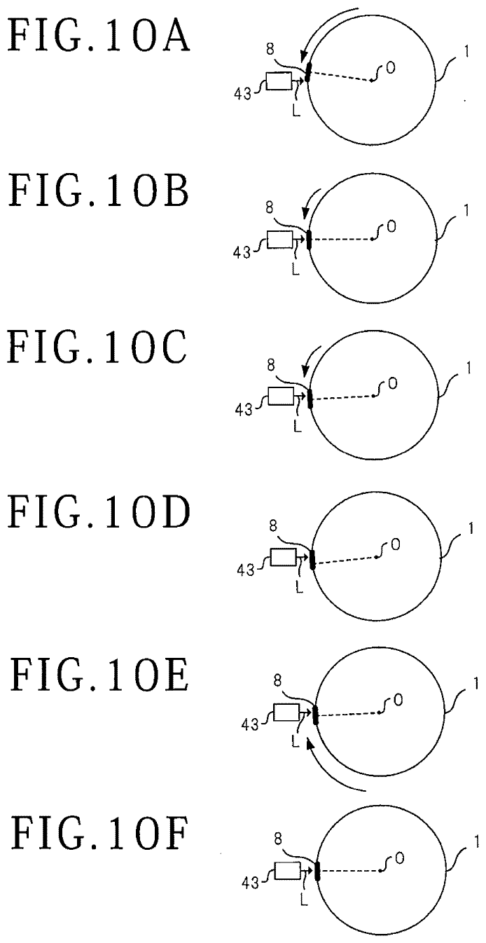

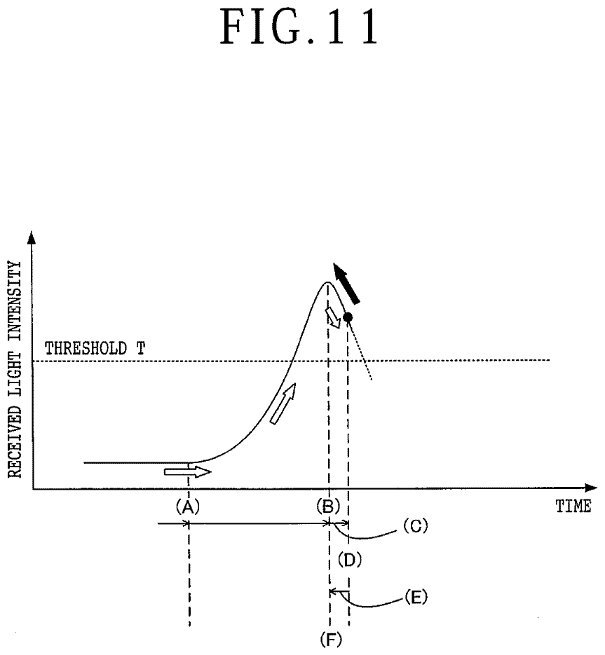

Next, description is made of the detection method for detecting the mark 8 according to the second embodiment with reference to FIG. 9 to FIG. 11. FIG. 9 is a flowchart of the detection method according to the second embodiment of the present invention, FIGS. 10A to 10F are views illustrating positions of the measurement light and the mark 8 in detecting steps, and FIG. 11 is a graph indicating the received light intensity of the reflected light in the detecting steps. Each broken line in FIGS. 10A to 10F indicates a line connecting the center O of the wafer 1 and the center of the mark 8 in the circumferential direction. In FIGS. 10A to 10F and FIG. 11, arrows indicate the rotation direction and the rotation speed. More specifically, in FIGS. 10A to 10F, the direction of each arrow represents the rotation direction, and the length of each arrow represents the rotation speed. In FIG. 11, white arrows represent a rotation direction different from that represented by a black arrow, and the length of each of the white arrows and the black arrow represents the rotation speed. A longer arrow means a higher rotation speed.

The detection method of the second embodiment includes a holding step S10, a first rotation step S11, a threshold detecting step S16, a mark center detecting step S14, a first rotation stopping step S12, a second rotation step S13, and a second rotation stopping step S15 as illustrated in FIG. 9. In the detection method of the present embodiment, the mark center detecting step S14 is carried out in the first rotation step S11.

The holding step S10 is a step of holding the wafer 1 on the rotary table 33. In the holding step S10, the wafer 1 is placed on the rotary table 33 in such a manner that the center O thereof coincides with the rotation axis P of the rotary table 33, and then is held under suction on the rotary table 33.

In the first rotation step S11, the rotary table 33 holding the wafer 1 thereon is rotated in one direction (hereinafter referred to as a normal rotation direction). At this time, the AC servo motor 31 rotates, and the orientation of the rotary table 33 is input as an encoder value to the controller 50. Meanwhile, the optical sensor 43 projects light from the light projector to the side surface of the wafer 1, and the received light intensity of reflected light received by the light receiver is input as received light intensity information to the controller 50.

At the position of FIG. 10A, the mark 8 deviates from the optical axis L of the optical sensor 43, and hence, the received light intensity of the reflected light is extremely low as indicated by (A) in FIG. 11. When the wafer 1 is further rotated in the normal rotation direction from the position of FIG. 10A, the mark 8 overlaps the optical axis L of the optical sensor 43, and hence, the received light intensity gradually increases as indicated in FIG. 11. It is to be noted that rotation in the normal rotation direction is indicated by a counterclockwise arrow in FIGS. 10A to 10F and is indicated by a white arrow in FIG. 11.

In the threshold detecting step S16, it is detected that the received light intensity of the reflected light exceeds the threshold set in advance. When the threshold detection section 57 detects the received light intensity of the measurement light exceeding a threshold T, the rotation speed control section 55 makes the rotation speed lower than the rotation speed adopted before the threshold T is exceeded.

At the position of FIG. 10B, the center of the mark 8 coincides with the optical axis L of the optical sensor 43, and hence, the received light intensity of the reflected light takes the maximum value as indicated by (B) in FIG. 11.

In the mark center detecting step S14, the area where the received light intensity of the reflected light takes the maximum value is determined as the center of the mark 8. Since, in the first rotation step S11, the received light intensity increases as the wafer 1 is rotated in the normal rotation direction, the mark center detection section 54 determines the area where the received light intensity takes the maximum value as the center of the mark 8.

When the wafer 1 is further rotated in the normal rotation direction from the position of FIG. 10B, the center of the mark 8 deviates from the optical axis L of the optical sensor 43, and hence, the received light intensity gradually decreases as indicated in FIG. 11. More specifically, at the position of FIG. 10C, although the mark 8 overlaps the optical axis L of the optical sensor 43, the center of the mark 8 has deviated from the optical axis L of the optical sensor 43, and hence, the received light intensity of the reflected light is lower than the maximum value as indicated by (C) in FIG. 11.

In the first rotation stopping step S12, it is detected that the received light intensity of the reflected light has started decreasing after reaching the maximum value, and the rotation of the wafer 1 in the normal rotation direction is then stopped. FIG. 10D indicates a state in which the rotation of the wafer 1 has been stopped in the first rotation stopping step S12. At the position of FIG. 10D, the center of the mark 8 deviates from the optical axis L of the optical sensor 43, and hence, the received light intensity of the reflected light is lower than the maximum value as indicated by (D) in FIG. 11.

In the second rotation step S13, the rotary table 33 holding the wafer 1 thereon is rotated in a reverse rotation direction that is a direction opposite to the normal rotation direction in which the rotary table 33 has been rotated in the first rotation step S11. At this time as well, the AC servo motor 31 rotates, and the orientation of the rotary table 33 is input as an encoder value to the controller 50. Meanwhile, the optical sensor 43 projects light from the light projector to the side surface of the wafer 1, and the received light intensity of reflected light received by the light receiver is input as received light intensity information to the controller 50. It is to be noted that rotation in the reverse rotation direction is indicated by a clockwise arrow in FIGS. 10A to 10F and is indicated by a black arrow in FIG. 11.

At the position of FIG. 10E, although the mark 8 overlaps the optical axis L of the optical sensor 43, the center of the mark 8 deviates from the optical axis L of the optical sensor 43. Hence, the received light intensity of the reflected light is lower than the maximum value as indicated by (E) in FIG. 11, but the received light intensity increases as the wafer 1 is further rotated in the opposite direction. The rotation speed in the second rotation step S13 need not necessarily be the same as the rotation speed adopted after the threshold T is exceeded, and is a relatively high rotation speed, for example, a rotation speed substantially the same as the rotation speed adopted before the threshold T is exceeded in the first rotation step S11. It is to be noted that the rotation speed in the second rotation step S13 may alternatively be the same as the rotation speed adopted after the threshold T is exceeded.

In the second rotation stopping step S15, the rotation of the wafer 1 is stopped immediately after reaching the position at which the center of the mark 8 has been detected in the mark center detecting step S14 carried out in the first rotation step S11. FIG. 10F indicates a state in which the rotation of the wafer 1 has been stopped in the second rotation stopping step S15. At the position of FIG. 10F, the center of the mark 8 coincides with the optical axis L of the optical sensor 43, and hence, the received light intensity of the reflected light takes the maximum value as indicated by (F) in FIG. 11.

As described above, after it is detected that the received light intensity of the light reflected by the mark 8 indicative of the crystal orientation has started decreasing after reaching the maximum value, the wafer 1 is rotated in the opposite direction, and then the rotation of the wafer 1 is stopped when the center of the mark 8 coincides with the measurement light. Consequently, an error between the measurement light and the center of the mark 8 at the stopped position can be minimized. Thus, the positioning accuracy can be enhanced as compared to the related-art case in which the rotation is stopped at the time when the amount of received light exceeds a threshold.

Moreover, in the present embodiment, the area where the received light intensity of the reflected light takes the maximum value is determined as the center of the mark 8 in the first rotation step S11, and the wafer 1 is returned in the second rotation step S13 to the position determined as the center of the mark 8.

In this case, in order to enhance the accuracy of detection of the mark 8, the threshold T is detected in the threshold detecting step S16, and the rotation speed adopted after the detection of the threshold T being exceeded is made lower than the rotation speed adopted before the threshold T is exceeded. This enhances the detection accuracy in the mark center detecting step S14 in the first rotation step S11, and thus enhances the accuracy of positioning the wafer 1. In contrast, the wafer 1 can be rotated at a relatively high speed in the second rotation step S13 and before the threshold T is exceeded in the first rotation step S11, so that the time taken until the end of the detection processing can be shortened. Furthermore, unlike the threshold for use in detecting the mark 8 as in the related-art case, this threshold T is for use in changing the rotation speed and hence does not require precise setting.

While the various embodiments have been described thus far with reference to the drawings, needless to say, the present invention is not limited those examples. It is obvious that those skilled in the art can easily conceive various modification examples and correction examples within the category described in the scope of the claims, and such examples are naturally construed as belonging to the technical scope of the present invention. Further, the constituent elements in the above embodiments may be combined freely without departing from the gist of the invention.

For example, illustrated in the embodiments described above is the processing apparatus 10 in which the optical axis L of the light projector and the light receiver of the optical sensor 43 is oriented to the side surface of the wafer 1, and the optical axis L has its height set coinciding with the height of the center of the wafer 1 in the thickness direction. However, the processing apparatus is not limited to this example.

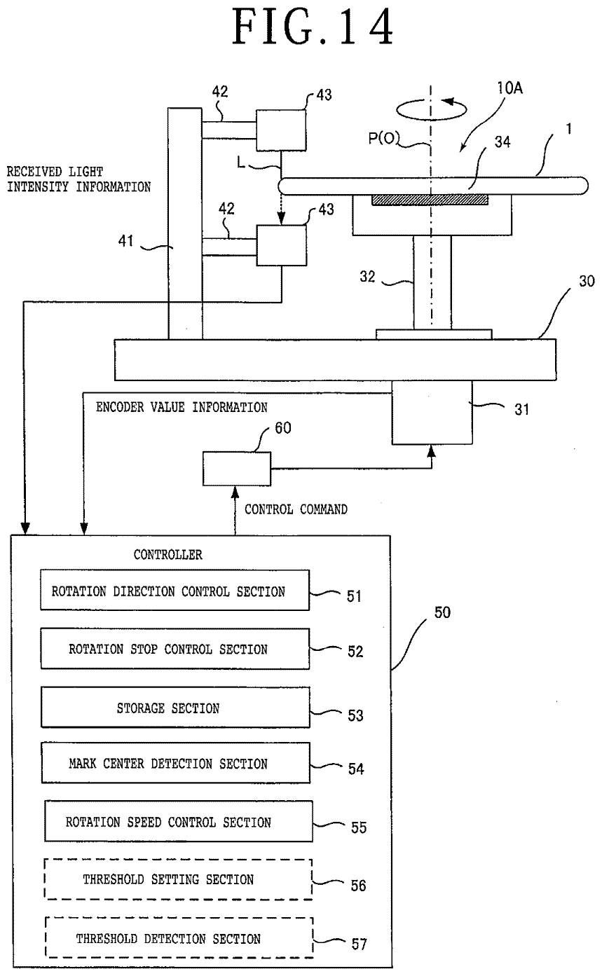

In a processing apparatus 10A according to a modification example, as illustrated in FIG. 14, a pair of brackets 42 are attached to the base frame 30 through the sensor post 41 in a manner being separated from each other in a vertical direction, an optical sensor 43 is attached to the pair of brackets 42. The optical sensor 43 has a light projector attached to the bracket 42 on the upper side and a light receiver attached to the bracket 42 on the lower side. The optical axis L of the light projector and the light receiver is oriented in a direction perpendicular to the planar direction (the front surface and the back surface lying parallel with each other) of the wafer 1. Light projected from the light projector of the optical sensor 43 is interrupted by the wafer 1. When the wafer 1 is rotated and the mark 8 has come to a position right below the optical sensor 43, the received light intensity of light that is transmitted through the wafer 1 and received by the light receiver becomes the maximum. It is to be noted that, since the other components of the processing apparatus 10A in this modification example are similar to those of the processing apparatus 10 in the embodiments described above, the same reference symbols are used in FIG. 14, and redundant description is omitted.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A detection method for detecting a mark that is formed at an outer peripheral edge of a semiconductor wafer and is indicative of crystal orientation, the detection method comprising:
irradiating the outer peripheral edge of the semiconductor wafer with measurement light while rotating the semiconductor wafer relative to the measurement light in one direction about a rotation axis passing through a center of the semiconductor wafer, receiving the measurement light transmitted or reflected by the mark, and detecting that received light intensity of the measurement light has started decreasing after reaching a maximum value;
then rotating the semiconductor wafer relative to the measurement light in a direction opposite to the one direction, and receiving the measurement light transmitted or reflected by the mark;
in the rotating the semiconductor wafer relative to the measurement light in the one direction and detecting that the received light intensity of the measurement light has started decreasing after reaching the maximum value or in the rotating the semiconductor wafer relative to the measurement light in the opposite direction and receiving the measurement light transmitted or reflected by the mark, determining an area where the received light intensity of the measurement light takes the maximum value as a center of the mark; and,
after the rotating the semiconductor wafer relative to the measurement light in the opposite direction and receiving the measurement light transmitted or reflected by the mark, stopping the rotation of the semiconductor wafer relative to the measurement light at the center of the mark.

2. The detection method according to claim 1, wherein, in the rotating the semiconductor wafer relative to the measurement light in the opposite direction and receiving the measurement light transmitted or reflected by the mark, an area where the received light intensity of the measurement light takes the maximum value is determined as the center of the mark, and the rotation of the semiconductor wafer relative to the measurement light is continued until determination of the center of the mark.

3. The detection method according to claim 2, wherein a rotation speed in the rotating the semiconductor wafer relative to the measurement light in the opposite direction and receiving the measurement light transmitted or reflected by the mark is set lower than a rotation speed in the rotating the semiconductor wafer relative to the measurement light in the one direction and detecting that the received light intensity of the measurement light has started decreasing after reaching the maximum value.

4. The detection method according to claim 1, wherein,
in the rotating the semiconductor wafer relative to the measurement light in the one direction and detecting that the received light intensity of the measurement light has started decreasing after reaching the maximum value, an area where the received light intensity of the measurement light takes the maximum value is determined as the center of the mark, and,
in the rotating the semiconductor wafer relative to the measurement light in the opposite direction and receiving the measurement light transmitted or reflected by the mark, the rotation of the semiconductor wafer relative to the measurement light is continued until the measurement light is located at the center of the mark.

5. The detection method according to claim 4, further comprising:
setting a threshold to the received light intensity of the measurement light; and
detecting the received light intensity of the measurement light exceeding the threshold, wherein,
in the rotating the semiconductor wafer relative to the measurement light in the one direction and detecting that the received light intensity of the measurement light has started decreasing after reaching the maximum value, when the received light intensity of the measurement light exceeds the threshold, a rotation speed is made lower than a rotation speed adopted before the threshold is exceeded.

6. The detection method according to claim 1, wherein
the mark is a flat mirror surface part formed at a position overlapping a chamfered portion at an outer periphery of the semiconductor wafer as viewed in a direction of the rotation axis, and,
in the rotating the semiconductor wafer relative to the measurement light in the one direction and detecting that the received light intensity of the measurement light has started decreasing after reaching the maximum value, and in the rotating the semiconductor wafer relative to the measurement light in the opposite direction and receiving the measurement light transmitted or reflected by the mark, the semiconductor wafer is irradiated with the measurement light from a side, and measurement light reflected by the flat mirror surface part is received.

7. A processing apparatus for detecting a mark that is formed at an outer peripheral edge of a semiconductor wafer and is indicative of crystal orientation, the processing apparatus comprising:
a holding table for holding the semiconductor wafer thereon;
a crystal orientation detection sensor having a light projector that irradiates the mark in the semiconductor wafer with measurement light and a light receiver that receives measurement light transmitted or reflected by the mark;
a rotation driving unit that rotates the holding table relative to the crystal orientation detection sensor about a rotation axis passing through a center of the holding table; and
a controller, wherein
the controller includes
a rotation direction control section that controls a rotation direction of the relative rotation,
a rotation stop control section that stops the relative rotation, and
a mark center detection section that determines an area where received light intensity of the measurement light takes a maximum value as a center of the mark,
the rotation direction control section changes the rotation direction of the relative rotation after, while the holding table is being rotated relative to the crystal orientation detection sensor in a predetermined direction, it is detected that the received light intensity of the measurement light has started decreasing after reaching the maximum value, and
the rotation stop control section stops the relative rotation at the center of the mark after the rotation direction of the relative rotation is changed.

8. The processing apparatus according to claim 7, wherein the controller further includes a rotation speed control section that controls a rotation speed of the relative rotation.

9. The processing apparatus according to claim 8, wherein
the mark center detection section detects the center of the mark while the holding table is being rotated relative to the crystal orientation detection sensor in a direction opposite to the predetermined direction, and
the rotation speed control section makes a rotation speed of the relative rotation in the opposite direction lower than a rotation speed of the relative rotation in the predetermined direction.

10. The processing apparatus according to claim 8, wherein
the controller further includes
a threshold setting section that sets a threshold to the received light intensity of the measurement light, and
a threshold detection section that detects the received light intensity of the measurement light exceeding the threshold,
the mark center detection section detects the center of the mark while the holding table is being rotated relative to the crystal orientation detection sensor in the predetermined direction, and,
when the threshold detection section detects the received light intensity of the measurement light exceeding the threshold, the rotation speed control section makes the rotation speed lower than the rotation speed adopted before the threshold is exceeded.
